(19) United States
(12) Patent Application Publication
(10) Pub. No.: US 2007/0224838 A1
(43) Pub. Date: Sep. 27, 2007

(54) Method of straining a silicon island for mobility improvement

(75) Inventors: Eric E. Vogt, Maple Grove, MN (US); Paul S. Fechner, Plymouth, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/389,703

(22) Filed: Mar. 27, 2006

(51) Int. Cl. H01L 21/31

(52) U.S. Cl. 438/787; 257/E21.468

(57) ABSTRACT

A method for improving mobility by bending a silicon island. Oxygen diffuses and reacts down a first axis of a pFET or NFET. This results in a partial oxidation of a buried-oxide/silicon island interface. The partial oxidation produces a thickness variation in the silicon island that creates a stress along the first axis. The stress along the first axis produces an increase in carrier mobility. Oxidation along a second, perpendicular, axis is inhibited to prevent a decrease in carrier mobility. The partial oxidation may be incorporated in SOI and STI based process flows. In addition, a dual-gate oxidation process may further enhance the observed increase in carrier mobility.

### FIELD

The present invention relates generally to the field of CMOS processing, and more particularly to a method of stressing a silicon island to improve FET mobility.

### BACKGROUND

In Complementary Metal Oxide Semiconductor (CMOS) processing, a variety of processing reactions may directly or indirectly impact the performance of CMOS devices, such as pMOS and nMOS Field Effect Transistors (FETs). CMOS devices typically include a variety of films that are made from materials such as silicon (Si), silicon nitride (Si₃N₄), poly-silicon, etc., which may each react differently to a variety of processing reactions.

One processing reaction in particular that may directly affect the performance of CMOS devices is the oxidation of Si to produce SiO₂. In this reaction, high temperature diffusion processes diffuse oxygen to an oxygen/silicon interface and oxygen reacts at the interface to form an oxide. This oxide may be a gate oxide or a liner oxide, for example. Although high temperature diffusion processes are useful for creating such oxides, in some instances, the diffusion and subsequent growth of SiO₂ in unfavorable areas of a CMOS device may produce deleterious effects. In particular, diffusing oxygen through an exposed Shallow Trench Isolation (STI) film and then reacting the oxygen with an active area island creates undesirable variations in device geometry and creates island stress that is not well accounted for in device modeling.

### SUMMARY

A method of improving mobility by bending a silicon island is presented. The method includes oxidizing a buried-oxide/silicon island interface of a CMOS device, such as a Field Effect Transistor (FET). The oxide/silicon interface is oxidized so as to create a thickness variation, or bending, along a first axis of the island. The bending along the first axis induces a stress that results in improved carrier mobility along an axis of the FET.

In order to stress the oxide/silicon interface along the first axis, trenches, such as those that are produced during an STI process are placed in close proximity to the oxide/silicon interface. Then, oxygen diffuses through these trenches and reacts at the interface. The oxygen reaction creates an oxide wedge having a profile directly attributed to the diffusion profile of the oxygen and results in a thickness variation in the silicon island, which effectively bends it upward. The oxidation of the island may be further optimized by preventing or inhibiting oxidation down a second axis that is perpendicular to the first axis.

As described above, the oxide/silicon interface may be located in a FET. The orientation of the first and second axes of the oxide/silicon interface may depend on the type of FET (i.e., p-type or n-type). In one example, the first axis is associated with the length of p-type FET (PFET) and the second axis is associated with the pFET's width. Stress along the length of the pFET improves the pFET's overall carrier mobility. In a contrasting example, the first axis is associated with the width of an n-type FET (nFET) and the second axis is associated the nFET's length. Stress along the width of the NFET improves the nFET's overall carrier mobility.

In order to incorporate oxide/silicon interface oxidation into a CMOS process flow, several example processes are disclosed. For example, a dual-gate oxidation process may be used. In such a process, a trench (e.g., an STI trench) is oxidized, etched, and re-oxidized in order to increasing bending along a first axis. A mask may inhibit oxidation down a second, perpendicular axis. By preventing oxidation down the second axis, a mobility decrease, which is attributed to stress down the second axis, may be avoided.

These as well as other aspects and advantages will become apparent to those of ordinary skill in the art by reading the following detailed description, with reference where appropriate to the accompanying drawings. Further, it is understood that this summary is merely an example and is not intended to limit the scope of the claims.

### BRIEF DESCRIPTION OF THE DRAWINGS

Certain examples are described below in conjunction with the appended drawing figures, wherein like reference numerals refer to like elements in the various figures, and wherein:

FIG. 1 is a top view of four silicon islands separated from each other by trenches;

FIG. 2 contains frames showing cross-sections of the silicon islands of FIG. 1;

FIG. 3 is a graph of pFET mobility vs. pFET island width;

FIG. 4 is a cross-section of an island from FIG. 1 being along its width;

FIG. 5 is a cross-section of the island of FIG. 4 having overlapping oxygen diffusion regions along its width;

FIG. 6 is a graph of pFET mobility vs. stress and pFET island width;

FIG. 7 is a graph of pFET mobility vs. pFET gate length;

FIG. 8 is a graph of pFET mobility vs. stress and pFET gate length;

FIG. 9 is a cross-section of an island from FIG. 1 being bent along its length;

FIG. 10 is a cross-section of the island of FIG. 9 having overlapping oxygen diffusion regions along its length; and

FIG. 11 is a flow diagram of a method of bending a silicon island.

### DETAILED DESCRIPTION

a) Oxidizing a Buried Oxide/Silicon Island Interface

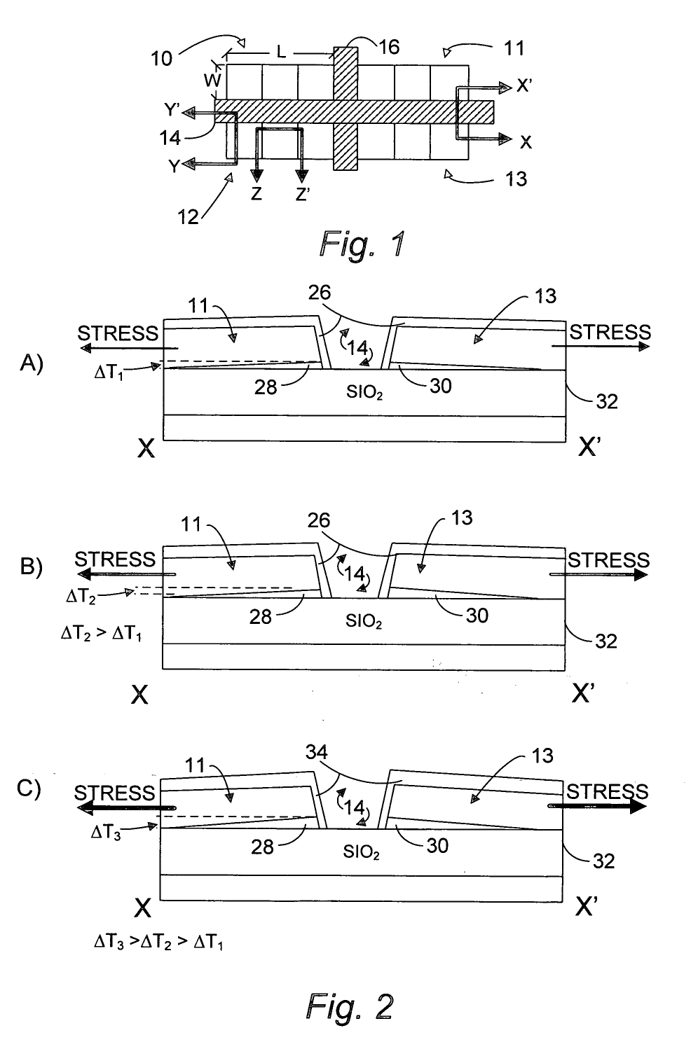

Turning now to the figures, FIG. 1 is a simplified block diagram showing a top view of four islands 10-13 located on top of an insulating layer. In most instances, the insulating layer is a buried oxide layer of an SOI substrate. Such an SOI substrate has a silicon layer located on top of the buried oxide and a bulk silicon substrate layer located below the insulating layer. Islands 10-13 may each eventually serve as an active area for a FET.

In order to provide electrical or physical isolation, trenches 14 and 16 run between islands 10-13. Trench 14 is parallel with a Length (L) of islands 10-13 and trench 16 is parallel with a Width (W) of islands 10-13. A Shallow Trench Isolation (STI) process may form trenches 14 and 16, for example (the STI process typically stops on the buried oxide). It should be understood that a variety of trenches may or may not be located in between islands 10-13. Overall, the purpose of the trenches, which will be described below, is to provide diffusion paths to a buried oxide/silicon island interface.

Generally, when an STI trench is formed (by a reactive ion etch, for example), the oxide/silicon interface is in close proximity to the STI trench (i.e., within several diffusion lengths). Because the oxide/silicon interface is within close proximity, subsequent thermally oxidative processing may cause oxide to diffuse to the oxide/silicon island interface, react, and create an oxide wedge in between a buried oxide and a silicon island. This oxide wedge effectively bends the silicon island upward and creates a stress along an axis of the silicon island. In order to demonstrate this effect, a series of frames A-C, taken from a cross-section X-X′ through islands 11 and 13, are shown in FIG. 2. Frame A is a simplified cross-section showing oxide wedge growth from a liner oxidation process and frames B and C are simplified cross-sections showing oxide wedge growth from a gate oxidation process. It should be understood that a variety of oxidation processes, in addition to liner and gate oxidation processes, may create the oxide wedges of frames A-C.

At frame A of FIG. 2, the liner oxidation process creates a liner oxide 26 that surrounds islands 11 and 13. In addition to growing liner oxide 26, the liner oxidation process also creates oxide wedges 28 and 30 in between islands 11 and 13 and a buried oxide 32. Oxide wedges 28 and 30 run parallel with the widths of islands 11 and 13 (see FIG. 1) and they grow from silicon islands 11 and 13. The diffusion that occurs at the oxide/silicon interface creates a slope in the wedges that falls towards the center of islands 11 and 13. Because the slope is attributed to the diffusion, the slope, or shape, may therefore take on a variety of forms.

Once the wedges begin to grow at the oxide silicon interface, the islands 11 and 13 begin to vary in thickness. The thickness variation across the silicon island, shown as ΔT₁, is positively correlative with a stress that is induced along the width of islands 11 and 13. In effect, the oxidation of the buried oxide/silicon island interfaces of islands 11 and 13 causes both islands to bend upward. Furthermore, subsequent oxidation processes may increase the bending by causing oxide wedges 28 and 30 to grow in thickness.

At frame B of FIG. 2, the gate oxidation process causes liner oxide 26 to grow in thickness. The thickness variation of islands 11 and 13 increases, shown as ΔT₂, and the stress along the width of islands 11 and 13 likewise increases. Because the liner oxide 26 is present during the gate oxidation, it acts as a diffusion barrier and reduces the growth rate of oxide wedge 28 and 30. If the liner oxide 26 is removed prior to the gate oxidation, more oxide will diffuse to the oxide/silicon interface and therefore grow thicker wedges 28 and 30.

At frame C, such a scenario is shown. Liner oxide 26 has been stripped and the gate oxidation process produces a gate oxide 34 which surrounds islands 11 and 13. In addition, the gate oxidation process increases the thickness of oxide wedges 28 and 30. Oxide wedges 28 and 30, in turn, produce a greater thickness variation, shown as ΔT₃, across islands 11 and 13. Because ΔT₃ is larger than ΔT₂, islands 11 and 13 bend more than they do in frame B. Accordingly, the bending induces more stress along the widths of islands 11 and 13.

By subjugating trench 14 to a cyclical treatment of etching and oxidation, oxide wedges 28 and 30 may grow to any desired thickness. A dual-gate oxidation process, for example, may provide such a cyclical treatment. Generally, dual-gate oxidation processes create at least two different gate oxide thicknesses on a common substrate. One gate oxide is thick and it is used for the gate of a high-voltage FET. The other gate is thin and it is used for the gate of a low-voltage FET.

At a first oxidative step of a dual-gate oxide process, a first oxide layer grows on top of silicon islands and it may also grow on the sidewalls of trenches (e.g., trench 14 and/or 16) that are proximal to the silicon islands. The first oxidative step, in a similar fashion to the description above, may increase a bending of the silicon islands. At a first etching step, an etch removes the first oxide layer from islands where low-voltage FETs are to be located. Then, a second oxidative step produces a thin, second oxide layer. If the etch removes the first oxide layer from the sidewalls of the trenches, the diffusing oxygen (in the second oxidative step) will not have to diffuse through oxidized sidewalls in order to reach the oxide silicon interface. Therefore, in areas where large silicon island bending is desired, the first oxide layer should be removed from the sidewalls prior to the second oxidative step.

b) Straining a Silicon Island to Reduce Mobility

As described above, silicon island bending has been viewed as undesirable. One assumption is that island bending decreases device performance. Indeed, some performance characteristics are proportional to device stress. One performance characteristic is mobility, μ. Changes in mobility cause changes to other key device characteristics, such as saturation current and threshold voltage.

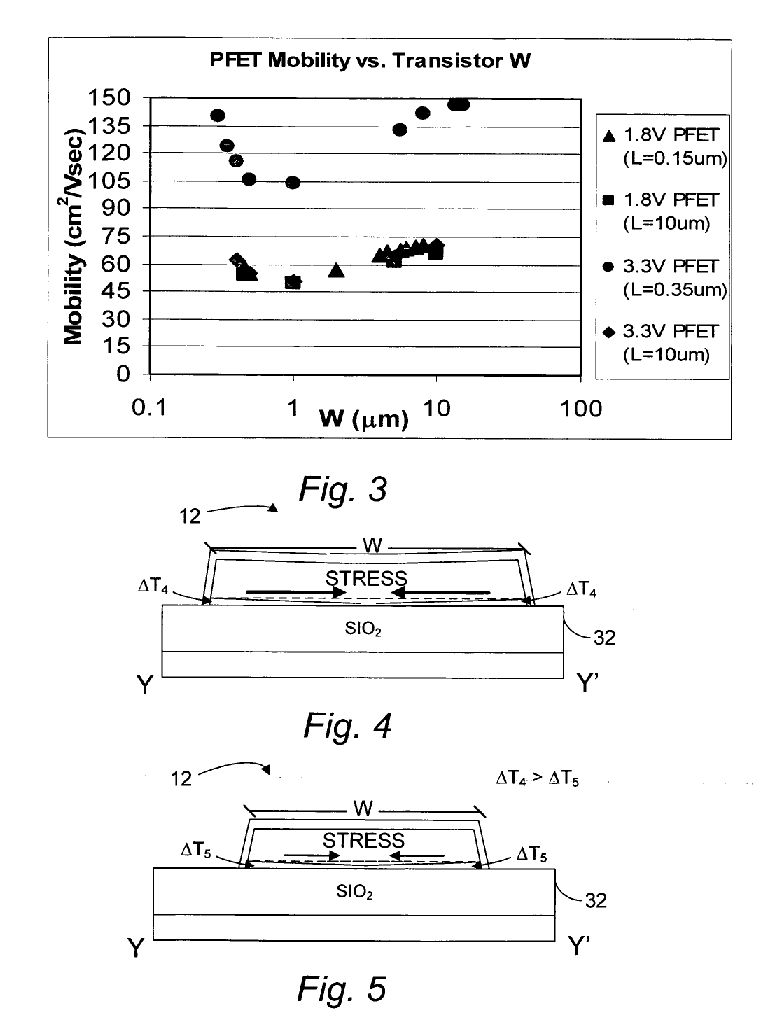

To illustrate this, FIG. 3 is a graph that plots mobility vs. channel width of various pFETs. In FIG. 3, all of the pFETs are subjected to an island stress that is caused by island bending along the widths of the island as described above. As the pFETs' widths decrease (until about 1 μm) the mobility of the pFETs likewise decreases. This is because as the widths decrease, the thickness variation occurs over a larger percentage of the width of a FET. For example, in FIG. 4 a cross section Y-Y′ (taken from FIG. 1) shows that as width decreases, the thickness variation ΔT₄ moves towards the center of island 12 and island bending increases. However, overlapping thickness variations, shown in FIG. 5, relieve stress as the thickness variation ΔT₅ is reduced and bending decreases. This explains why the pFETs having sub-micron widths, shown in FIG. 3, begin to increase in mobility.

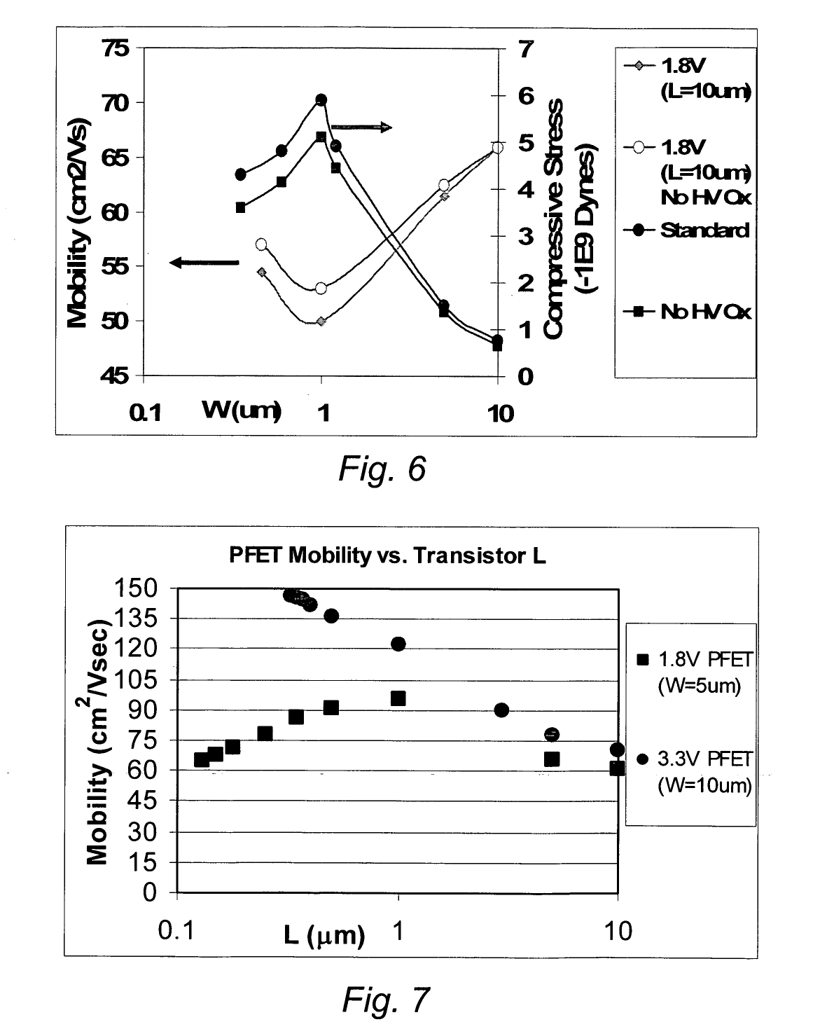

To reinforce this overlap concept, FIG. 6 is a graph illustrating predicted stress (using SUPREM 4 simulations) and mobility vs. width for various pFETs. As a pFET's width decreases to 1 μm, stress increases and mobility decreases. As the widths move past 1 μm and towards the sub-micron regime, stress decreases and mobility increases. Again, in the sub-micron regime, the overlapping oxide diffusions underneath a silicon island relieve island bending and stress. The significance of this effect will be discussed further with reference to FIGS. 7-10.

Returning to FIG. 3, one sole pFET has a higher mobility than the other pFETs. Evidently, stress along the width of a pFETs is not the only factor that determines mobility. This sole pFET, it turns out, has an optimal island bending along its length. In fact, what will be described below is that stress along the length of a pFET increases mobility. Moreover, depending on the type of FET an island is located in, island bending along a preferred axis increases mobility.

c) Straining a Silicon Island to Enhance Mobility

To demonstrate this stress effect, FIG. 7 is a graph of pFET mobility vs. various gate lengths. As gate length (and overall transistor length) decreases, mobility increases (until a gate length of about 1 μm). Interestingly, however, the high-voltage (3.3 V) pFET continues to increase in mobility as it overtakes 1 μm and enters the sub-micron regime. The low-voltage pFET (1.8V) begins to decrease in mobility when it enters the sub-micron regime. It is believed that the mobility decrease of the low-voltage pFET is due to an aggressive halo implant to roll the low-voltage pFET device threshold up. This effectively increases the vertical electric field at gmmax which reduces mobility. Because the source and drains contribute at least 0.8 μm to the overall transistor length, the mobility decrease is not attributed to an overlap of the oxidation at the buried oxide/silicon island interface, as described with reference to FIGS. 3-4.

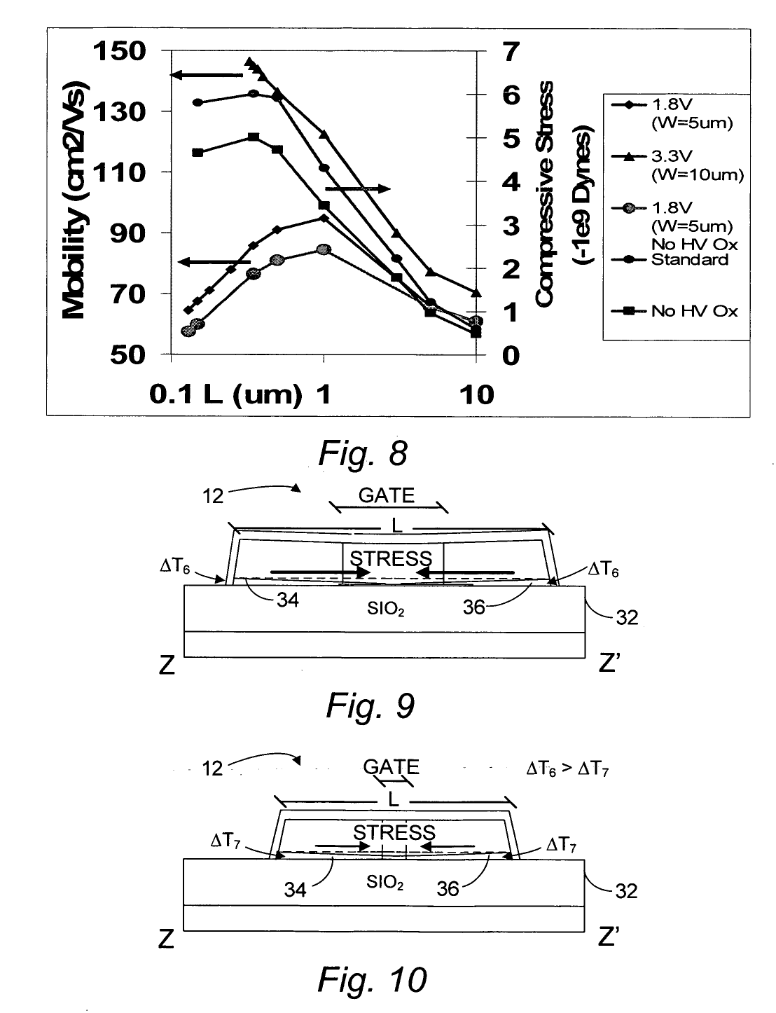

As an additional example, FIG. 8 is a graph plotting simulated stress and mobility vs. gate length for a variety of pFETs. In this example, the low-voltage (1.8V) pFETs exhibit a mobility decrease in the sub-micron regime. The high voltage and standard process pFETs, however, continue to increase in mobility well into the sub-micron regime. Again, the decrease in mobility observed in some of the pFETs is likely due to halo implants and not an overlap of oxide diffusion regions under a silicon island.

Generally, as the island bending increases and the length of a pFET decreases, stress moves towards the center of the pFET (and under a gate). To demonstrate this, FIG. 9 is a cross section Z-Z′, taken from FIG. 1, along the length of island 12. In FIG. 9, an oxidative step has created wedges 34 and 36. Wedges 34 and 36 bend island 12 upwards. A thickness variation, indicated by ΔT₆, induces a stress along the length of the island 12. As shown in FIG. 10, if the overall island length enters the sub-micron regime, oxide wedges 34 and 36 will overlap and the overall thickness variation, indicated by ΔT₇, will decrease. As a result of such a decrease, the stress along the length of FET 12 will decrease and so will carrier mobility that is along the length of island 12.

Overall, to bend a silicon island for a mobility improvement, the island should be bent so that stress is promoted along one axis and inhibited along another. In particular, for a silicon island in a pFET, stress should be promoted along the length of the pFET and inhibited along the width. The contrary is true for a silicon island in an NFET. That is, stress should be promoted along the width of the nFET and inhibited along the length.

d) A Method of Straining a Silicon Island to Enhance Mobility

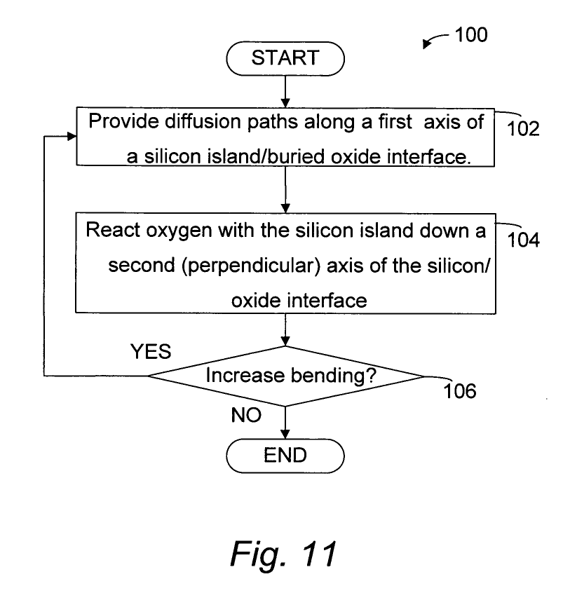

A method 100 of straining a silicon island is presented in FIG. 11. By application of method 100, island bending along a preferred axis may yield an enhanced mobility in a FET. At block 102 of method 100, diffusion paths are provided along a first axis of a silicon island/buried oxide interface. If the silicon island is located in a pFET, the first axis may be along the width of the pFET. Alternatively, if the silicon island is located in an nFET, the first axis may be along the length of the nFET. In either case, an etching step may create trenches (such as STI trenches) that flank the island and consequently provide diffusion paths. These trenches should be located in close proximity to a buried oxide/silicon island so that during an oxidative step, oxygen does not encounter a significant diffusion barrier.

Once the diffusion paths are provided, oxygen diffuses to the oxide/silicon interface and reacts with the island along a second (perpendicular) axis, shown at block 104. As a result, the island bends and induces a stress along the second axis. If the island is in a pFET, the second axis may be parallel to the length of the island. If the island is in an NFET, the second axis may be parallel to the width of the island.

In order for oxygen to diffuse and react at the oxide/silicon interface, a variety of oxidative processes may be used. As described above, these processes include gate oxidations, dual-gate oxidations, liner oxidations, annealing steps, etc. It should be understood that the method 100 is not limited to the types of oxidative steps that are used.

After the oxygen reaction, the bending of the island can be increased, or method 100 may be completed, as shown at decision block 106. If the bending is to be increased, diffusion paths are once again provided along the first axis of the silicon/oxide interface. This may simply include etching oxide that formed in the trenches at block 104 and thus reducing the distance through which the oxygen diffuses until it reaches the oxide/silicon interface.

Although method 100 allows for oxidation along the second axis, additional measures may be taken to prevent oxidation down the first axis. A hard mask, for example, may prevent diffusion of oxygen to the oxide/silicon interface in a direction that is parallel with the first axis. Alternatively, by simply not forming trenches that flank a second axis of the island, oxygen diffusion down the first axis may also be inhibited.

e) Conclusion

The presented methods for bending a silicon island, when carried out, provide a mobility enhancement for a FET. Although only a handful of oxidative, etching, and other processing steps have been described, it should be understood that the described methods may be undertaken using a variety of alternative processing steps. In addition, alternative structures, such as other types of micro-electronic devices may benefit from island bending. Also, additional structures may be added or removed to enhance island bending. For example, by increasing the number of contact fingers in the source or drain regions, island bending may be modified. More contact fingers added along one axis may decrease bending. Likewise, using only one contact finger may optimize bending. It should be understood, therefore, that the illustrated examples are examples only and should not be taken as limiting the scope of the present invention. The claims should not be read as limited to the described order or elements unless stated to that effect. Therefore, all examples that come within the scope and spirit of the following claims and equivalents thereto are claimed as the invention.

We claim:

1. A method of straining a silicon island, the method comprising:
providing first and second trenches that flank a first axis of the silicon island; and
diffusing oxygen through the first and second trenches to a buried oxide interface below the silicon island, thereby causing an oxidation of the silicon island that increases a thickness variation in the oxide/silicon interface along a second axis of the silicon island, the second axis being substantially perpendicular to the first axis.

2. The method as in claim 1, wherein the thickness variation increases a stress of the silicon island along the second axis.

3. The method as in claim 2, wherein the thickness variation is symmetric about the first axis.

4. The method as in claim 3, wherein the thickness variation is attributed to a diffusion profile associated with the oxygen diffusion through the first and second trenches.

5. The method as in claim 2, wherein the stress increase is positively correlative with carrier mobility parallel with the second axis.

6. The method as in claim 1, wherein the oxide/silicon interface is located within a Field Effect Transistor (FET).

7. The method as in claim 6, wherein the first axis is associated with a width of the FET and the second axis is associated with a length of the FET.

8. The method as in claim 6, wherein the stress increase is centered under a gate of the FET.

9. The method as in claim 8, wherein the stress increase is positively correlative with a carrier mobility associated with the FET.

10. The method as in claim 8, wherein the FET has a single source contact aligned with a center of the first axis and a single drain contact aligned with the center of the first axis.

11. The method as in claim 8, wherein the first and second axis are substantially parallel with a plane of the buried oxide/silicon interface.

12. A strained silicon island, comprising first and second axes, the first axis being bent by an oxidation of the silicon island that increases a stress along the first axis for the purpose of increasing carrier mobility.

13. The silicon island as in claim 12, wherein the silicon island is located within a p-type Field Effect Transistor (pFET), and wherein the first axis is associated with a width of the pFET.

14. The silicon island as in claim 12, wherein the oxide/silicon interface is located within an n-type Field Effect Transistor (nFET), and wherein the first axis is associated with a length of the nFET.

15. The silicon island as in claim 13, wherein the FET is fabricated in a Silicon-On-Insulator (SOI) substrate.

16. The silicon island as in claim 13, wherein the silicon island is bent during a first oxidation step of a dual-gate oxide process and it is bent during a second oxidation step of the dual-gate oxide process.

17. The silicon island as in claim 13, wherein oxidation along a second axis perpendicular to the first axis is inhibited to prevent bending of the second axis.

18. A method of straining a silicon island, the method comprising:
oxidizing a portion of a first axis of a oxide/silicon interface, the oxidation increasing a stress along the first axis; and
inhibiting an oxidation of a second axis of the oxide/silicon interface, the second axis being substantially perpendicular to the first axis.

19. The method as in claim 18, wherein the first axis defines a length of a p-type Field Effect Transistor (PFET) and the second axis defines a width of the pFET.

20. The method as in claim 18, wherein the first axis defines a width of an n-type Field Effect Transistor (nFET) and the second axis defined a length of the nFET.
